(19) United States
(12) Patent Application Publication
(10) Pub. No.: US 2025/0096202 A1
(43) Pub. Date: Mar. 20, 2025

(54) STACKED SEMICONDUCTOR DEVICE

(71) Applicant: Micron Technology, Inc., Boise, ID (US)

(72) Inventors: Bharat Bhushan, Taichung (TW); Bret K. Street, Meridian, ID (US); Akshay N. Singh, Boise, ID (US); Kunal R. Parekh, Boise, ID (US); Wei Zhou, Boise, ID (US)

(21) Appl. No.: 18/788,541

(22) Filed: Jul. 30, 2024

Related U.S. Application Data
(60) Provisional application No. 63/539,264, filed on Sep. 19, 2023.

(51) Int. Cl. H01L 25/065; H01L 23/00; H10B 80/00

(52) U.S. Cl. CPC H01L 25/0657; H01L 24/05; H10B 80/00; H01L 2224/08146; H01L 2225/06541

(57) ABSTRACT

A semiconductor device assembly is provided. The semiconductor device assembly includes a logic die, a first plurality of stacked memory dies electrically coupled with the logic die, and a second plurality of stacked memory dies mounted on and electrically coupled with the first plurality of stacked memory dies. A first dielectric material is disposed around the first plurality of stacked memory dies. A second dielectric material is disposed at the first dielectric material and surrounding the second plurality of stacked memory dies. A third dielectric material is disposed between the first plurality of stacked memory dies and the second plurality of stacked memory dies and between the first dielectric material and the second dielectric material.

### CROSS-REFERENCE TO RELATED APPLICATION(S)

The present application claims priority to U.S. Provisional Patent Application No. 63/539,264, filed Sep. 19, 2023, the disclosure of which is incorporated herein by reference in its entirety.

### TECHNICAL FIELD

The present disclosure generally relates to semiconductor device assemblies and more particularly relates to a stacked semiconductor device.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly.

FIG. 2 illustrates a simplified schematic cross-sectional view of a semiconductor device assembly in accordance with an embodiment of the present technology.

FIGS. 3-9 illustrate simplified schematic perspective and cross-sectional views of a series of steps for fabricating semiconductor device assemblies in accordance with an embodiment of the present technology.

FIG. 10 illustrates a simplified schematic cross-sectional view of a semiconductor device assembly in accordance with an embodiment of the present technology.

FIG. 11 illustrates a schematic view of a system that includes a semiconductor device assembly configured in accordance with an embodiment of the present technology.

FIG. 12 illustrates a method of making a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor devices with high circuit density. Thus, additional techniques may be required to continue the growth in capability of semiconductor devices.

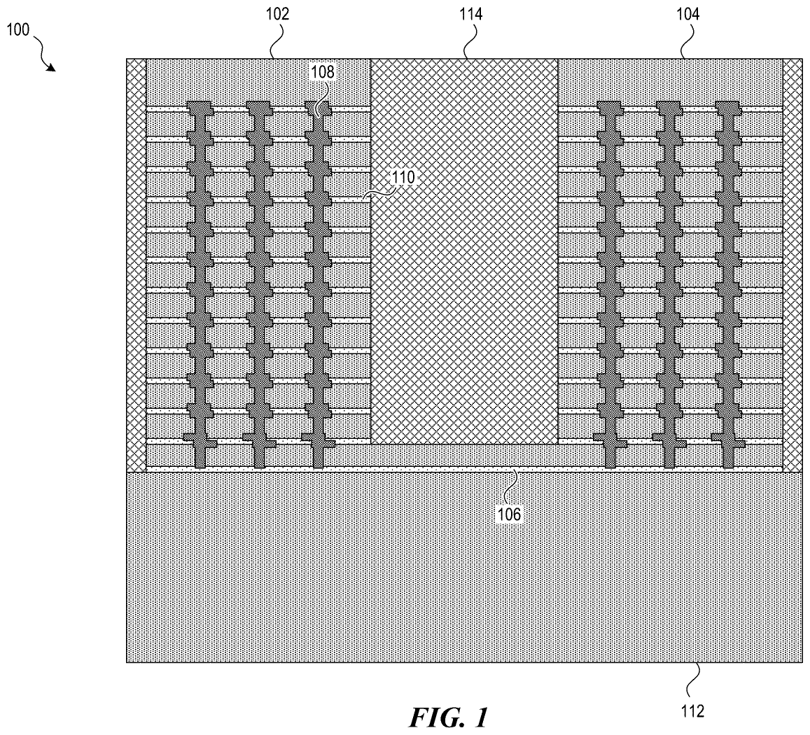

One such technique is to implement multiple circuit components within a single package. For example, stacked semiconductor devices enable multiple semiconductor dies to be stacked on top of one another to increase the number of circuit elements within a package without increasing its footprint. To produce a stacked semiconductor device, multiple wafers may be stacked together and diced into individual die stacks. The die stacks may then be packaged into a packaged semiconductor device to be implemented within a larger electronic device. Some techniques, however, may struggle to produce large stacks of semiconductor dies due, for example, to the current limitations of modern die bonders. One such technique is shown by way of example in FIG. 1.

FIG. 1 illustrates a semiconductor device assembly 100 that includes a first plurality of semiconductor dies 102 (e.g., memory dies) and a second plurality of semiconductor dies 104 (e.g., memory dies) assembled onto a wafer of semiconductor dies 106 (e.g., logic dies). The first plurality of stacked semiconductor dies 102 and the second plurality of stacked semiconductor dies 104 may be singulated from a stack of semiconductor wafers. The stack of semiconductor wafers may be created by bonding wafers that include a plurality of semiconductor dies (e.g., wafer-wafer bonding). The wafers may be bonded in a front-to-back arrangement such that a front side (e.g., an active side) of a first wafer at which circuitry of the semiconductor dies is implemented is mounted to a back side (e.g., an inactive side) of a second wafer. One or more of the semiconductor wafers may include through-silicon vias (TSVs 108) that are exposed at the back side of the semiconductor wafers. The semiconductor wafers may be coupled through hybrid bonding. For example, the semiconductor wafers may be electrically coupled through interconnects (e.g., metal-metal interconnects) and bonded through a dielectric material 110 (e.g., dielectric block). In aspects, the interconnects may be copper-copper (Cu—Cu) interconnects. The dielectric material 110 may include any appropriate dielectric material, for example, silicon oxide, silicon nitride, silicon carbide, silicon carbon nitride, or the like.

Once the semiconductor wafers have been bonded into a stack, stacks of semiconductor dies can be singulated from the stack of wafers and assembled onto a wafer of semiconductor dies 106. The wafer of semiconductor dies 106 may include a plurality of semiconductor dies having a different arrangement than the semiconductor dies of the first plurality of stacked semiconductor dies 102 or the second plurality of stacked semiconductor dies 104. For example, the wafer of semiconductor dies 106 may include logic dies, and the first plurality of stacked semiconductor dies 102 or the second plurality of stacked semiconductor dies 104 may include memory dies. As a result, the wafer of semiconductor dies 106 may not be bonded with the stack of wafers through a wafer-wafer bond. Instead, the wafer of semiconductor dies 106 may be adhered to a carrier substrate 112 to help the device withstand processing, and the first plurality of stacked semiconductor dies 102 and the second plurality of stacked semiconductor dies 104 may be electrically coupled to the wafer of semiconductor dies 106. After the pluralities of stacked semiconductor dies are assembled onto the wafer of semiconductor dies 106, a mold resin 114 may be disposed on the wafer of semiconductor dies 106 around the plurality of stacked semiconductor dies 102 and the plurality of stacked semiconductor dies 104. The device can then be removed from the carrier wafer 112, the stacked semiconductor dies and the various semiconductor dies on the wafer of semiconductor dies 106 can be diced, and the singulated stacks of semiconductor dies may be packaged into a semiconductor device.

Various challenges may present themselves when designing stacked semiconductor devices using this technique, particularly with large die stacks. For example, current bonders may fail to bond a large stack of semiconductor dies (e.g., wafers). Moreover, yield may be reduced when stacking multiple wafers of semiconductor dies due to the effectiveness of hybrid bonding. For example, each hybrid bond between wafers (e.g., wafer-wafer bond) may have an effectiveness of X percent, where “X” is a number between 0 and 100, and a hybrid bond from a die stack to a wafer of semiconductor dies (e.g., chip-wafer bond) may be Y percent effective, where “Y” is a number between 0 and 100 that is less than X. Thus, to implement a stack of 12 dies assembled onto a wafer of semiconductor dies, 11 wafer-wafer hybrid bonds and one chip-wafer hybrid bond may be performed. Accordingly, using the technique illustrated in FIG. 1, stacked semiconductor devices may be implemented with a percent yield equal to X¹¹Y. Further, a stacked semiconductor device created using the technique illustrated in FIG. 1 may have a high thermal resistance, which can cause failure of the stacked semiconductor device in operation, particularly in tightly compacted semiconductor devices (e.g., like the device illustrated in FIG. 1).

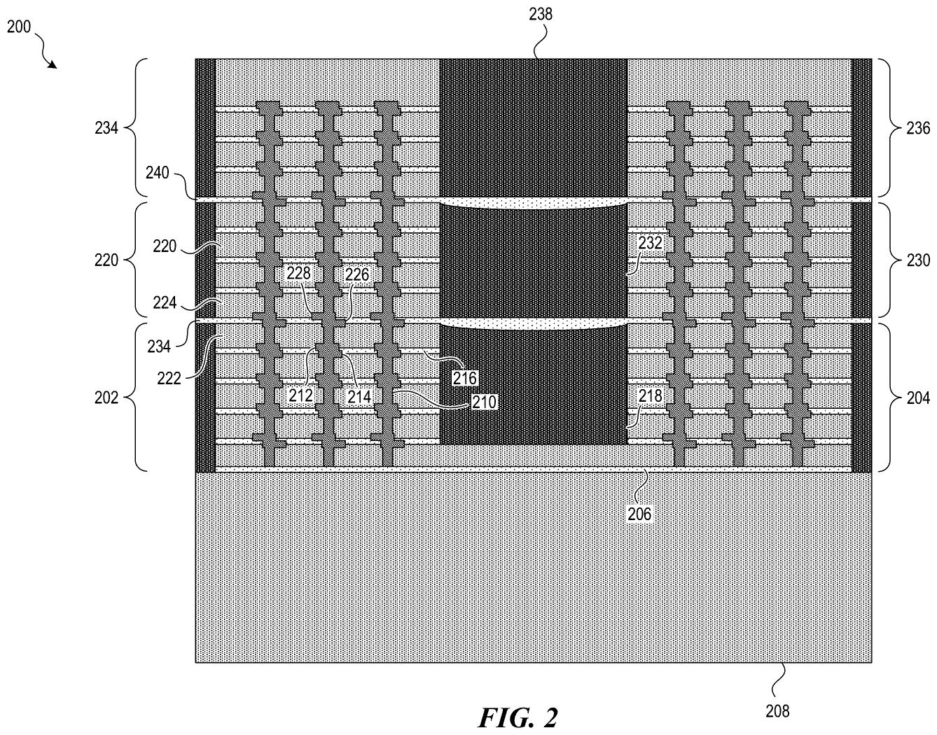

To address these drawbacks and others, various embodiments of the present technology provide semiconductor device assemblies that implement a stack of semiconductor dies. A semiconductor device assembly is provided. The semiconductor device assembly includes a logic die, a first plurality of stacked memory dies electrically coupled with the logic die, and a second plurality of stacked memory dies mounted on and electrically coupled with the first plurality of stacked memory dies. A first dielectric material is disposed around the first plurality of stacked memory dies. A second dielectric material is disposed at the first dielectric material and surrounding the second plurality of stacked memory dies. A third dielectric material is disposed between the first plurality of stacked memory dies and the second plurality of stacked memory dies and between the first dielectric material and the second dielectric material. In doing so, a stacked semiconductor device can be assembled, which may be produced with a higher yield or have a low thermal resistance. An example semiconductor device assembly is shown in FIG. 2.

FIG. 2 illustrates a semiconductor device assembly 200 that includes a first plurality of semiconductor dies 202 (e.g., memory dies) and a second plurality of semiconductor dies 204 (e.g., memory dies) assembled onto a wafer of semiconductor dies 206 (e.g., logic dies). The first plurality of semiconductor dies 202 may be assembled (e.g., chip-wafer bonded) onto the wafer of semiconductor dies 206 at a first semiconductor die (e.g., at a first lateral location). The wafer of semiconductor dies 206 may be assembled onto a carrier substrate 208 (e.g., through an adhesive or dielectric material) to enable the semiconductor device assembly 200 to withstand processing. The first plurality of stacked semiconductor dies 202 and the second plurality of stacked semiconductor dies 204 may be singulated from a stack of semiconductor wafers. The stack of semiconductor wafers may be created by bonding wafers that include a plurality of semiconductor dies (e.g., wafer-wafer bonding). The wafers may be bonded in a front-to-back arrangement such that a front side (e.g., an active side) of a first wafer at which circuitry of the semiconductor dies is disposed is mounted to a back side (e.g., an inactive side) of a second wafer. One or more of semiconductor dies of the first plurality of stacked semiconductor dies 202 may include TSVs 210 that are exposed at the back side of the semiconductor dies. Contact pads 212 may be formed at the front side of the semiconductor dies and contact pads 214 may be formed at the exposed TSVs 210 at the back side of the semiconductor dies.

The semiconductor dies may electrically couple at the contact pads 212 and the contact pads 214 through interconnects. The semiconductor dies within the first plurality of stacked semiconductor dies 202 may be coupled through hybrid bonding. For example, the semiconductor wafers may be electrically coupled through interconnects (e.g., metal-metal interconnects) and bonded through a dielectric material 216 (e.g., dielectric block). In aspects, the interconnects may be copper-copper (Cu—Cu) interconnects. The dielectric material 216 may include any appropriate dielectric material, for example, silicon oxide, silicon nitride, silicon carbide, silicon carbon nitride, or the like. Given that the interconnects may be formed from wafer-wafer bonding, the interconnects between the contact pads 212 and the contact pads 214 between pairs of dies of the first plurality of stacked semiconductor dies 202 may be smaller than interconnects formed by chip-wafer or die-wafer bonding. For example, the interconnects may be less than 500 nanometers (nm), 400 nm, 300 nm, 200 nm, 100 nm, 50 nm, or the like.

The second plurality of semiconductor dies 204 may be similarly fabricated and diced from a stack of semiconductor wafers. The second plurality of semiconductor dies 204 may be assembled (e.g., chip-wafer bonded) onto the wafer of semiconductor dies 206. The second plurality of semiconductor dies 204 may be assembled onto the wafer of semiconductor dies 206 at a second semiconductor die (e.g., at a second lateral location). A dielectric material 218 (e.g., oxide fill) may be disposed between the first plurality of stacked semiconductor dies 202 and the second plurality of stacked semiconductor dies. The dielectric material 218 may be disposed at the wafer of semiconductor dies 206 or the carrier wafer 208 between the first plurality of stacked semiconductor dies 202 and the second plurality of stacked semiconductor dies 204 (e.g., and any other plurality of stacked semiconductor dies assembled onto the wafer of semiconductor dies 206). In aspects, the dielectric material 218 may be different than a dielectric material 216 between the dies of the first plurality of stacked semiconductor dies 202 (e.g., or any other plurality of stacked semiconductor dies assembled onto the wafer of semiconductor dies 206). For example, the dielectric material 218 can be an oxide. In aspects, the dielectric material 218 may be any appropriate dielectric material (e.g., silicon oxide, silicon nitride, silicon carbide, silicon carbon nitride, etc.). In aspects, the dielectric material 218 may fill gaps between the first plurality of stacked semiconductor dies 202 and the second plurality of stacked semiconductor dies 204 (e.g., and any other plurality of stacked semiconductor dies assembled onto the wafer of semiconductor dies 206) to re-create a wafer structure for additional pluralities of stacked semiconductor dies to be assembled onto.

In some implementations, the dielectric material 218 can provide additional manufacturing paths over other possible materials (e.g., a mold compound). For example, the dielectric material 218 can have beneficial thermal properties that enable the semiconductor device to withstand greater temperatures. As a result, annealing processes used to form metal-metal interconnects that connect to subsequent stacks (e.g., plurality of stacked semiconductor dies 220) can be performed at a higher temperature (e.g., 350 degrees Celsius versus 180 degrees Celsius). Furthermore, the dielectric material 218 can be less prone to particulates, which can reduce the risk of particles contaminating the semiconductor device assembly 200.

A third plurality of stacked semiconductor dies 220 may be fabricated through wafer-wafer bonding, and the third plurality of stacked semiconductor dies 220 may be diced from the stacked wafers. The third plurality of stacked semiconductor dies 220 may be assembled (e.g., mounted) onto the first plurality of stacked semiconductor dies 202. For example, a top semiconductor die 222 of the first plurality of stacked semiconductor dies 202 may couple (e.g., electrically, mechanically) with a bottom semiconductor die 224 of the third plurality of stacked semiconductor dies 220. The back side of the top semiconductor die 222 may include contact pads 226 at exposed TSVs, and the front side of the bottom semiconductor die 224 may include contact pads 228. The third plurality of stacked semiconductor dies 220 may be chip-wafer bonded to the first plurality of stacked semiconductor dies 202 through hybrid bonding.

Given that the third plurality of stacked semiconductor dies 220 may couple with the first plurality of stacked semiconductor dies 202 through chip-wafer bonding, the interconnects between the contact pads 226 at the top semiconductor die 222 and the contact pads 228 at the bottom semiconductor die 224 may be larger than the interconnects within the first plurality of semiconductor dies 202 (e.g., or any other plurality of stacked semiconductor dies formed through wafer-wafer bonding) between the contact pads 212 and the contact pads 214. For example, the interconnects between the contact pads 226 and the contact pads 228 may be larger than 500 nm, 400 nm, 300 nm, 200 nm, or the like. Moreover, the contact pads 226 and the contact pads 228 may have a larger misalignment (e.g., lateral misalignment) than the contact pads 212 and the contact pads 214. For example, the interconnects between the contact pads 226 and the contact pads 228 may be formed through chip-wafer bonding, and thus, the interconnects may be formed without the benefit of aligning full wafers. In contrast, the interconnects between the contacts pads 212 and the contact pads 214 may be formed through wafer-wafer bonding of two similarly arranged wafers. Accordingly, the contact pads 212 and the contact pads 214 may have a smaller misalignment.

A fourth plurality of stacked semiconductor dies 230 may be fabricated through wafer-wafer bonding, and the fourth plurality of stacked semiconductor dies 230 may be diced from the stacked wafers. The fourth plurality of stacked semiconductor dies 220 may be assembled (e.g., mounted) onto the second plurality of stacked semiconductor dies 202, similar to the third plurality of stacked semiconductor dies 220 and the second plurality of stacked semiconductor dies 204 (e.g., chip-wafer bonding). In this way, the fourth plurality of stacked semiconductor dies 230 may electrically couple with the second plurality of stacked semiconductor dies 204 through interconnects.

A dielectric material 232 (e.g., oxide fill or any other material discussed with respect to the dielectric material 218) may be disposed on the dielectric material 218 between the third plurality of stacked semiconductor dies 220 and the fourth plurality of stacked semiconductor dies 230. The third plurality of stacked semiconductor dies 220, fourth plurality of stacked semiconductor dies 230, and the dielectric material 232 may be coupled to the first plurality of stacked semiconductor dies 202, second plurality of stacked semiconductor dies 204, and the dielectric material 218, respectively, at a bond interface through a dielectric material 234 (e.g., dielectric block). The dielectric material 234 may include a same or different material than the dielectric material 216. In aspects, the dielectric material 234 may be thicker between the dielectric material 218 and the dielectric material 232 in comparison to the thickness of the dielectric material 234 between the third plurality of stacked semiconductor dies 220 and the first plurality of stacked semiconductor dies 202 or the fourth plurality of stacked semiconductor dies 230 and the second plurality of stacked semiconductor dies 204. This difference in thickness may be due to a topography of the bonding surface formed from the top of the first plurality of stacked semiconductor dies 202, the second plurality of stacked semiconductor dies 204, and the dielectric material 218 due to planarizing the bonding surface.

The semiconductor device assembly 200 may include any number of additional pluralities of stacked semiconductor dies stacked onto the third plurality of stacked semiconductor dies 220 and the fourth plurality of stacked semiconductor dies 230. The additional pluralities of stacked semiconductor dies may be stacked through a similar technique to that described with respect to the first plurality of stacked semiconductor dies 202, the second plurality of stacked semiconductor dies 204, the third plurality of stacked semiconductor dies 220, and the fourth plurality of stacked semiconductor dies 230. As illustrated, a fifth plurality of stacked semiconductor dies 234 is assembled onto and electrically coupled with the third plurality of stacked semiconductor dies 220, and a sixth plurality of stacked semiconductor dies 236 is assembled onto and electrically coupled with the fourth plurality of stacked semiconductor dies 230. A dielectric material 238 (e.g., oxide fill or any other material discussed with respect to the dielectric material 218) may be disposed on the dielectric material 232 between the fifth plurality of stacked semiconductor dies 234 and the sixth plurality of stacked semiconductor dies 236.

A dielectric material 240 (e.g., dielectric block, similar to the dielectric material 234) may be disposed between the fifth plurality of stacked semiconductor dies 234, the sixth plurality of stacked semiconductor dies 236, and the dielectric material 238 and the third plurality of stacked semiconductor dies 234, the fourth plurality of stacked semiconductor dies 236, and the dielectric material 232, respectively. In aspects, a top die of the fifth plurality of stacked semiconductor dies 234 or the sixth plurality of stacked semiconductor dies 236 may be thicker than the other dies within the stacked semiconductor device. The top die of the fifth plurality of stacked semiconductor dies 234 or the sixth plurality of stacked semiconductor dies 236 may not include TSVs. In some implementations, the dielectric material 238 may be disposed over top of the top die in the fifth plurality of stacked semiconductor dies 234 or the sixth plurality of stacked semiconductor dies 236.

Although illustrated in a particular configuration, a stacked semiconductor device assembly could include a different configuration than shown in FIG. 2. For example, a stacked semiconductor device assembly could include a different number of stacks of semiconductor dies, a different number of pluralities of stacked semiconductor dies within each stack, a different number of semiconductor dies within each stack, a different number of semiconductor dies within each plurality of stacked semiconductor dies, and so on. In some cases, the semiconductor device assembly 200 can include 10, 20, 50, 100, 200, 300, 400, 500, or any number therebetween stacks of semiconductor dies. In some implementations, each stack of semiconductor dies may include 6, 8, 12, 15, 20, or any number therebetween semiconductor dies. In aspects, each of the pluralities of stacked semiconductor dies can include 2, 3, 4, 5, 10, or any number therebetween semiconductor dies. In some implementations, each of the stacks of semiconductor dies can include 2, 3, 4, 5, 10, or any number therebetween pluralities of stacked semiconductor dies within each stack of semiconductor dies.

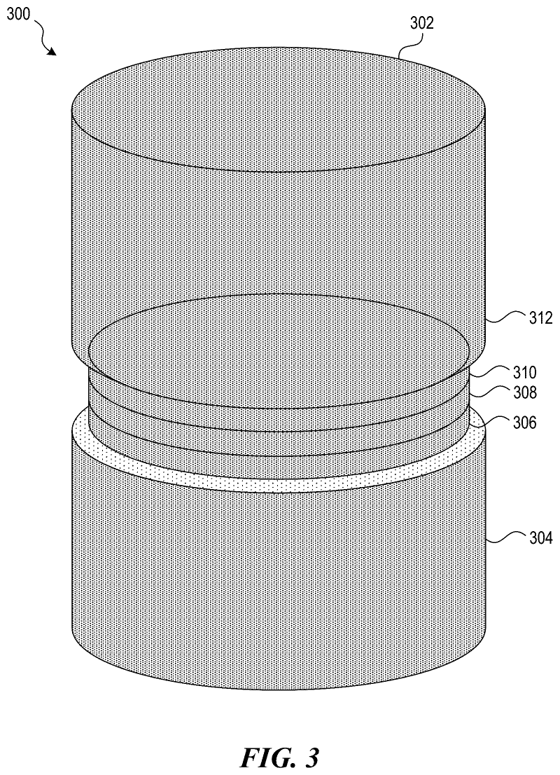

This disclosure now turns to a series of steps for fabricating semiconductor device assemblies in accordance with embodiments of the present technology. Specifically, FIGS. 3-9 illustrate simplified schematic perspective and cross-sectional views of a series of steps for fabricating semiconductor device assemblies in accordance with an embodiment of the present technology. The steps are illustrated with respect to specific embodiments for ease of description. However, the steps described with respect to FIGS. 3-9 could be performed to fabricate semiconductor device assemblies in accordance with other embodiments.

Beginning with FIG. 3 at stage 300, a stack of semiconductor wafers 302 is provided. The stack of semiconductor wafers 302 is adhered to a carrier wafer 304 to enable the semiconductor wafers to withstand processing. A first semiconductor wafer 306 is adhered to the carrier wafer 304 (e.g., in a face down arrangement). TSVs may be exposed at a back side of the first semiconductor wafer 306, and contact pads may be disposed thereat. A second semiconductor wafer 308 may be electrically coupled to the first semiconductor wafer 306 at the contact pads through wafer-wafer bonding (e.g., in a front-to-back arrangement). The second semiconductor wafer 308 may be electrically coupled to the first semiconductor wafer 306 through hybrid bonding to bond the wafers through a dielectric material (e.g., dielectric block) and metal-metal interconnects. A third semiconductor wafer 310 may be electrically coupled to the second semiconductor wafer 308 through a similar process. A fourth semiconductor wafer 312 may be coupled to the third semiconductor wafer 310 at contact pads on the back side of the third semiconductor wafer 310. The fourth semiconductor wafer 312 may be thicker than each of the other semiconductor wafers. In aspects, each of the plurality of semiconductor wafers may have a similar arrangement of semiconductor dies. The stack of semiconductor wafers 302 may then be removed from the carrier wafer 304 for further processing.

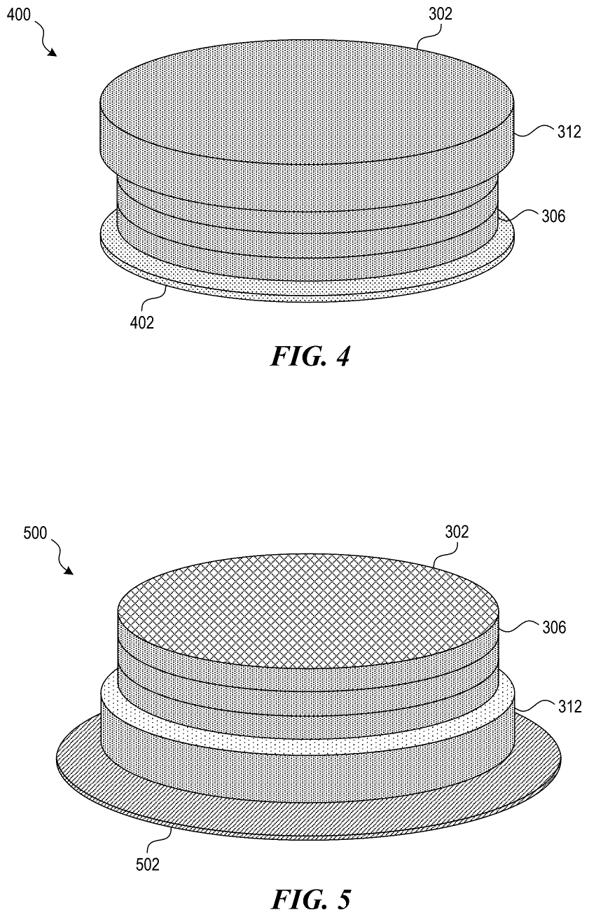

Turning to FIG. 4 at stage 400, the stack of semiconductor wafers 302 is adhered to back grinding tape 402 to enable the stack of semiconductor wafers 302 to be thinned. The first semiconductor wafer 306 may be adhered to back grinding tape 402 in a face down position so that the back side of the fourth semiconductor wafer 312 is exposed for thinning. The back side of the fourth semiconductor wafer 312 can be thinned through any appropriate method, for example, using back grinding, chemical-mechanical planarization (CMP), or the like. In aspects, the back grinding does not expose TSVs at the back side of the fourth semiconductor wafer 312. After thinning, the back grinding tape 402 can be removed from the stack of semiconductor wafers 302 to enable the stack of semiconductor wafers 302 to be diced.

Turning to FIG. 5 at stage 500, the stack of semiconductor wafers 302 is diced into multiple pluralities of stacked semiconductor dies. The stack of semiconductor wafers 302 may be adhered to dicing tape 502 at the back side of the fourth semiconductor wafer 312. The front side of the first semiconductor wafer 306 may be exposed to enable the stack of semiconductor wafers 302 to be diced between the plurality of semiconductor dies. Once diced, the multiple pluralities of stacked semiconductor dies may be singulated from one another. The multiple pluralities of stacked semiconductor dies may then be tested and assembled into packages.

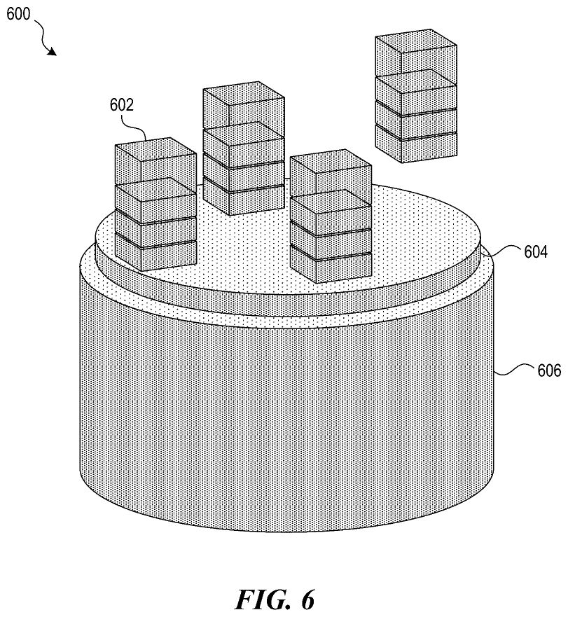

Turning next to FIG. 6 at stage 600, the multiple pluralities of stacked semiconductor dies 602 are assembled onto a wafer of semiconductor dies 604 (e.g., logic dies). The pluralities of stacked semiconductor dies 602 may be electrically coupled to the wafer of semiconductor dies 604 at respective semiconductor dies or at the same semiconductor die (e.g., at different lateral locations) using chip-wafer bonding. The wafer of semiconductor dies 604 may be assembled onto a carrier wafer 606 to enable the semiconductor device assembly to withstand processing. The wafer of semiconductor dies 604 may have a different arrangement of semiconductor dies from the multiple pluralities of stacked semiconductor dies 602. The pluralities of stacked semiconductor dies 602 may be selected from the stacked semiconductor dies diced from the stack of semiconductor wafers. The pluralities of stacked semiconductor dies 602 may be selected based on a quality of the pluralities of stacked semiconductor dies 602. The quality of the pluralities of stacked semiconductor dies 602 may be determined by probing the stacked semiconductor dies diced from the stack of semiconductor wafers. In this way, the highest quality stacks of semiconductor dies, or “known good cubes,” may be selected from the stacked semiconductor dies diced from the stack of semiconductor wafers to improve yield.

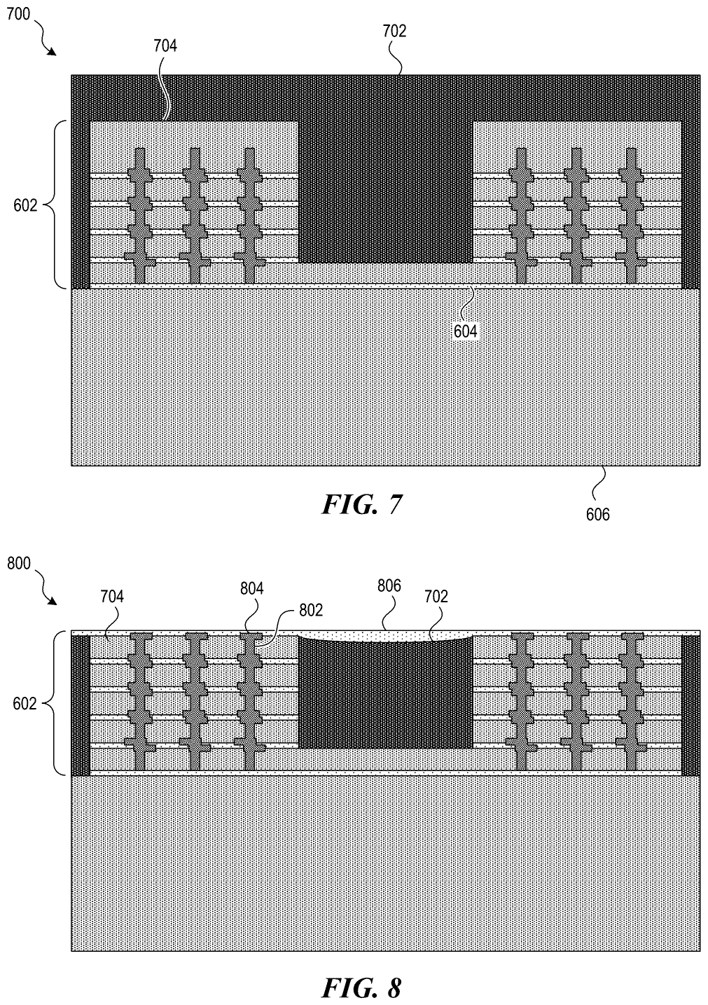

Turning next to FIG. 7 at stage 700, a dielectric material 702 (e.g., oxide fill) may be disposed between the pluralities of stacked semiconductor dies 602. The dielectric material 702 may be disposed on the logic wafer 604. In aspects, the dielectric material 702 may be disposed over top dies 704 of the pluralities of stacked semiconductor dies 602. In this way, the pluralities of stacked semiconductor dies 602 may be embedded in the dielectric material 702. In some implementations, the dielectric material 702 may be disposed on the carrier wafer 606. The dielectric material 702 may then be thinned to expose TSVs in the top dies 704 and provide a planar surface at which additional pluralities of stacked semiconductor dies electrically couple.

Turning next to FIG. 8 at stage 800, material may be removed from a top surface of the dielectric material 702 and the top dies 704 may be thinned to expose TSVs 802 at a back side of the top dies 704. In aspects, material may be removed through back grinding, CMP, or the like. Contact pads 804 (e.g., copper pads) may be disposed at the exposed TSVs 802 to enable additional pluralities of stacked semiconductor dies 602 to be electrically coupled thereto. In some cases, removing the material from the top surface of the dielectric material 702 and the top dies 704 may create a recession at the dielectric material 702 between the pluralities of stacked semiconductor dies 602. A dielectric material 806 (e.g., silicon block) may be disposed at the top dies 704 and the dielectric material 702 to create a planar top surface to which additional pluralities of stacked semiconductor dies can be mounted. In this way, the top surface may act as a reconstructed wafer to enable additional pluralities of stacked semiconductor dies to be stacked thereon. Given that the dielectric material 702 is recessed between the pluralities of stacked semiconductor dies 602, the thickness of the dielectric material 806 at the dielectric material 702 may be greater than the thickness of the dielectric material 806 at the top dies 704. In aspects, the contact pads 804 may be exposed through the dielectric material 806 to enable interconnects to be formed thereat.

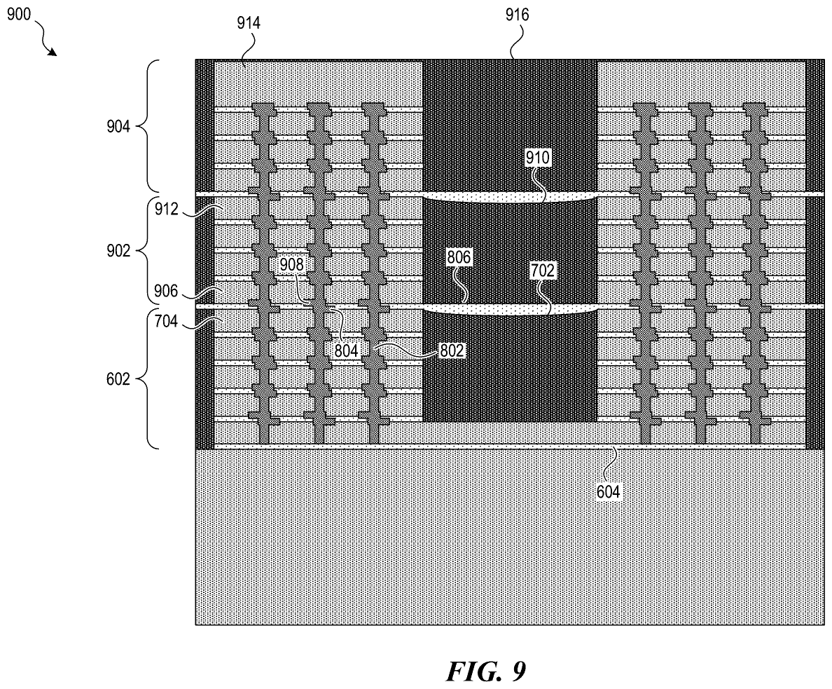

Turning next to FIG. 9 at stage 900, additional pluralities of stacked semiconductor dies 902 and additional pluralities of stacked semiconductor dies 904 may be assembled (e.g., chip-wafer bonded) onto the pluralities of stacked semiconductor dies 602. The additional pluralities of stacked semiconductor dies 902 or the additional pluralities of stacked semiconductor dies 904 may be fabricated by repeating the steps described with respect to FIGS. 3-8 with the reconstructed wafer formed from the pluralities of stacked semiconductor dies 902 acting as the wafer of semiconductor dies 604. Bottom dies 906 of the pluralities of stacked semiconductor dies 902 may include contact pads 908 at which interconnects are formed between the top dies 704 and the bottom dies 906. The contact pads 908 and the contact pads 804 may be aligned, and the interconnects may be formed between them. In aspects, the contact pads 908 and the contact pads 804 may have a larger misalignment than the interconnects formed within the pluralities of stacked semiconductor dies 602.

Once the pluralities of stacked semiconductor dies 902 are assembled onto the pluralities of stacked semiconductor dies 602, the dielectric material 910 (e.g., oxide fill) and the top dies 912 of the pluralities of stacked semiconductor dies 902 may be thinned to expose TSVs, and a dielectric material 914 (e.g., dielectric block) may be disposed to provide a bonding surface for the pluralities of stacked semiconductor dies 904. The pluralities of stacked semiconductor dies 904 may then be assembled onto the pluralities of stacked semiconductor dies 902 through a technique similar to the one used to assemble the pluralities of stacked semiconductor dies 902 on the pluralities of stacked semiconductor dies 602. In aspects, however, top dies 914 of the stacked semiconductor dies 904 need not be thinned to expose TSVs as no additional pluralities of stacked semiconductor dies are assembled on the stacked semiconductor dies 904. The stacked dielectric material (e.g., dielectric material 916, dielectric material 910, and dielectric material 702) and the wafer of semiconductor dies 604 may then be diced to separate the semiconductor device assembly into multiple stacks of semiconductor dies.

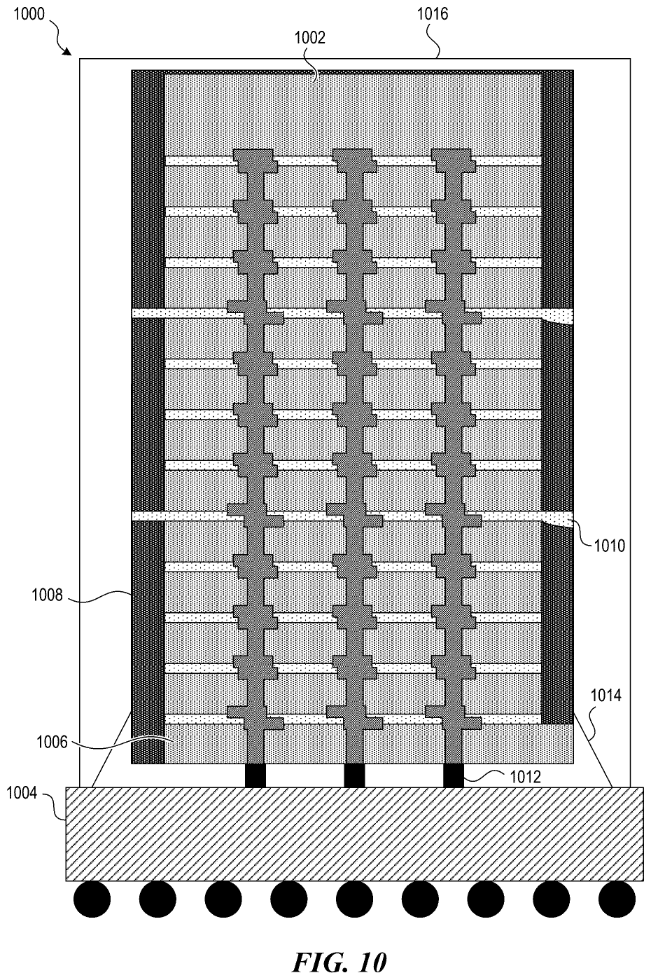

In some cases, the wafer of semiconductor dies 604 is diced to produce a single stack of semiconductor dies (e.g., a high-bandwidth memory (HBM) device), as illustrated in FIG. 10. In other cases, the wafer of semiconductor dies 604 can be diced to produce a semiconductor die (e.g., of the wafer of semiconductor dies 604) with multiple stacks of semiconductor dies coupled therewith at multiple lateral locations. For example, the semiconductor device can include a central processing unit (CPU) or graphics processing unit (GPU) with a plurality of memory die stacks coupled therewith (e.g., a tightly coupled dynamic random access memory (TCDRAM) device).

In some implementations, the multiple stacks of semiconductor dies produced using the technique described with respect to FIGS. 3-9 may be produced with higher yield than the stacks of semiconductor dies produced using the technique described with respect to FIG. 1. For example, the pluralities of stacked semiconductor dies 602, the pluralities of stacked semiconductor dies 902, and the pluralities of stacked semiconductor dies 904 may be selected as “known good cubes.” Thus, the reliability of each of these pluralities of stacked semiconductor dies may be assured prior to assembling them within the semiconductor device. These pluralities of stacked semiconductor dies are then electrically coupled through hybrid bonds. As illustrated, the semiconductor device assembly includes three chip-wafer hybrid bonds. For example, a first chip-wafer bond between the wafer of semiconductor dies 604 and the pluralities of stacked semiconductor dies 602, a second chip-wafer bond is formed between the pluralities of stacked semiconductor dies 602 and the pluralities of stacked semiconductor dies 902, and a third chip-wafer bond is formed between the pluralities of stacked semiconductor dies 902 and the pluralities of stacked semiconductor dies 904. Using the same Y percent effectiveness of a chip-wafer bond discussed with respect to FIG. 1, the techniques described with respect to FIGS. 3-9 may produce a stacked semiconductor device with a percent yield equal to Y 3. The resulting stacked semiconductor device may then be packaged into a semiconductor device, an example of which is shown in FIG. 10.

FIG. 10 illustrates a simplified schematic semiconductor device assembly 1000 in accordance with an embodiment of the present technology. As can be seen with reference to FIG. 10, the semiconductor device assembly 1000 can include a stack of semiconductor dies 1002 assembled onto a package-level substrate 1004 (e.g., printed circuit board (PCB), semiconductor substrate, etc.). The semiconductor dies 1002 may be fabricated using any of the techniques described with respect to FIGS. 3-9. In doing so, the semiconductor dies 1002 may include a base die 1006 (e.g., logic die) and a stack of pluralities of stacked semiconductor dies (e.g., memory dies). Each of the pluralities of stacked semiconductor dies may be singulated from a wafer stack. Thus, the interconnects within each of the pluralities of stacked semiconductor dies may be formed through wafer-wafer bonding, and the interconnects between the pluralities of stacked semiconductor dies may be formed through chip-wafer bonding. Dielectric material 1008 (e.g., oxide fill) may surround each of the pluralities of stacked semiconductor dies. In this way, the stack of semiconductor dies 1002 may be protected by sidewalls of the dielectric material 1008. A dielectric material 1010 (e.g., dielectric block) may bond adjacent pluralities of stacked semiconductor dies and adjacent portions of the dielectric material 1008.

Interconnects 1012 may be formed between contact pads at a bottom surface of the base die 1006 and contact pads at the substrate 1004 to enable electrical signals to pass between the stack of semiconductor dies 1002 and the substrate 1004. The semiconductor dies 1002 may include traces, lines, vias, or other electrical connection structures that connect circuitry at the semiconductor dies 1002 to contact pads at which interconnects are implemented. Any of the semiconductor dies within the stack of semiconductor dies 1002 may include one or more TSVs to enable electrical signals to be passed between the semiconductor dies within the stack of semiconductor dies 1002.

The substrate 1004 can further include package-level contact pads that provide external connectivity (e.g., via solder balls) to the stack of semiconductor dies 1002 (e.g., power, ground, and I/O signals) through traces, lines, vias, and other electrical connection structures in the substrate 1004 that electrically connect the package-level contact pads to contact pads at an upper surface of the substrate 1004. An underfill material 1014 (e.g., capillary underfill) can be provided between the stack of semiconductor dies 1002 (e.g., the base die 1006) and the substrate 1004 to provide electrical insulation to the interconnects 1012 and structurally support the stack of semiconductor dies 1002. The assembly 1000 can further include an encapsulant material 1016 (e.g., mold resin compound or the like) that at least partially encapsulates the stack of semiconductor dies 1002 and the substrate 1004 to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-10 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

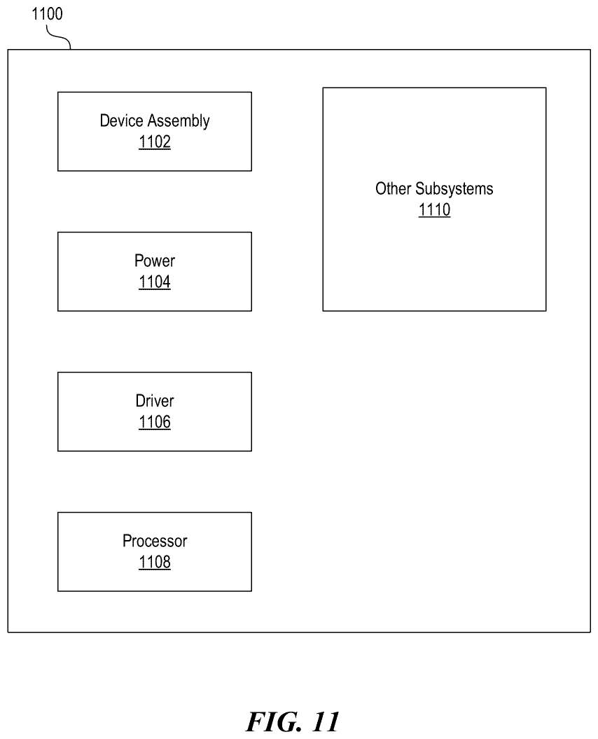

Any one of the semiconductor devices and semiconductor device assemblies described above with reference to FIGS. 1-10 can be incorporated into any of a myriad of larger and/or more complex systems, a representative example of which is system 1100 shown schematically in FIG. 11. The semiconductor die stack as provided in FIGS. 1-10 can communicate with one or more devices within the system 1100 using one or more standard protocols. For example, the memory stacks may communicate using an HBM protocol. Alternatively, the memory stacks may communicate using a TCDRAM protocol. The system 1100 can include a semiconductor device assembly 1102 (e.g., a discrete semiconductor device), a power source 1104, a driver 1106, a processor 1108, and/or other subsystems or components 1110. The semiconductor device assembly 1102 can include features generally similar to those of the semiconductor device assemblies described above with reference to FIGS. 1-10. The resulting system 1100 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, vehicles, appliances and other products. Components of the system 1100 may be housed in a single unit or distributed over multiple, interconnected units (e.g., through a communications network). The components of the system 1100 can also include remote devices and any of a wide variety of computer readable media.

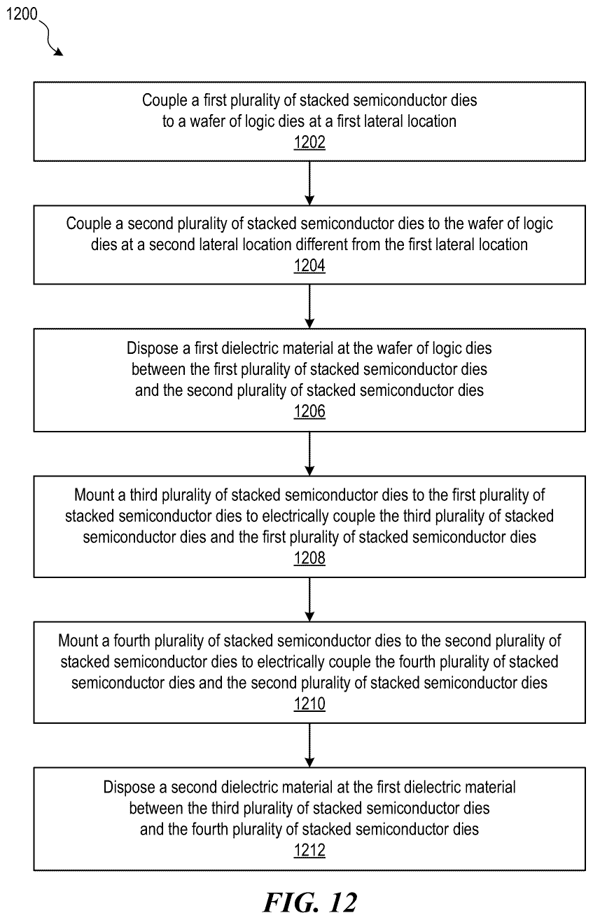

FIG. 12 illustrates an example method 1200 for fabricating a semiconductor device assembly in accordance with an embodiment of the present technology. The method 1200 may, for illustrative purposes, be described with respect to features, components, or elements of FIGS. 1-11. Although illustrated in a particular configuration, one or more operations of the method 1200 may be omitted, repeated, or reorganized. Additionally, the method 1200 may include other operations not illustrated in FIG. 12, for example, operations detailed in one or more other methods described herein.

At 1202, a first plurality of stacked semiconductor dies 202 is coupled (e.g., mechanically and electrically) to a wafer of logic dies 206 at a first lateral location. In aspects, the first plurality of stacked semiconductor dies 202 may be coupled to a first logic die of the wafer of logic dies 206. At 1204, a second plurality of stacked semiconductor dies 204 is coupled (e.g., mechanically and electrically) to the wafer of logic dies 206 at a second lateral location that is different from the first lateral location. In aspects, the second plurality of stacked semiconductor dies 204 may be coupled to a second logic die of the wafer of logic dies 206.

At 1206, a first dielectric material 218 is disposed at the wafer of logic dies 206 between the first plurality of stacked semiconductor dies 202 and the second plurality of stacked semiconductor dies 204. In some implementations, the first plurality of stacked semiconductor dies 202 can include a first top die 222, and the second plurality of stacked semiconductor dies 204 can include a second top die. The first dielectric material 218 can be disposed at the first top die 222 and the second top die such that an upper surface of the first dielectric material 218 extends from the first top die 222 and the second top die. In aspects, the first dielectric material, the first top die 222, and the second top die may be thinned to expose first TSVs 210 and second TSVs in the first top die 222 and the second top die, respectively. First contact pads 226 can be formed at the first TSVs 210 and second contact pads can be formed at the second TSVs. A third dielectric material 234 may be disposed at the first dielectric material 218, the first top die 222, and the second top die.

At 1208, a third plurality of stacked semiconductor dies 220 is mounted to the first plurality of stacked semiconductor dies 202 to electrically couple the third plurality of stacked semiconductor dies 220 and the first plurality of stacked semiconductor dies 202. In aspects, the third plurality of stacked semiconductor dies 220 is electrically coupled to the first plurality of stacked semiconductor dies 202 at the first contact pads 226 formed on the first TSVs 210. In aspects, providing the third plurality of stacked semiconductor dies 220 includes electrically coupling a plurality of semiconductor wafers to form a stack of semiconductor wafers and dicing the stack of semiconductor wafers to create the third plurality of stacked semiconductor dies 220. In some cases, dicing the stack of semiconductor wafers may create multiple pluralities of stacked semiconductor dies, which are probed to determine their quality. In this way, the third plurality of stacked semiconductor dies 220 can be selected from the multiple pluralities of stacked semiconductor dies based on the determined quality. For example, the third plurality of stacked semiconductor dies 220 may be a “known good cube” of the multiple pluralities of stacked semiconductor dies.

At 1210, a fourth plurality of stacked semiconductor dies 230 is mounted to the second plurality of stacked semiconductor dies 204 to electrically couple the fourth plurality of stacked semiconductor dies 230 and the second plurality of stacked semiconductor dies 204. In aspects, the fourth plurality of stacked semiconductor dies 230 is electrically coupled to the second plurality of stacked semiconductor dies 204 at the second contact pads formed on the second TSVs. At 1212, a second dielectric material 232 is disposed at the first dielectric material 218 between the third plurality of stacked semiconductor dies 220 and the fourth plurality of stacked semiconductor dies 230. The third dielectric material 234 may be disposed between the third plurality of stacked semiconductor dies 220, the fourth plurality of stacked semiconductor dies 230, and the second dielectric material 232, and the first plurality of stacked semiconductor dies 220, the second plurality of stacked semiconductor dies 204, and the first dielectric material 218, respectively.

In some cases, the method 1200 may include dicing the wafer of logic dies 206, the first dielectric material 218, and the second dielectric material 232 effective to create a first stacked semiconductor device assembly and a second stacked semiconductor device assembly. The first stacked semiconductor device assembly may include the first logic die, the first plurality of stacked semiconductor dies 202, and the third plurality of stacked semiconductor dies 220. The second stacked semiconductor device assembly may include the second logic die, the second plurality of stacked semiconductor dies 204, and a fourth plurality of stacked semiconductor dies 230. In some cases, the resulting stacked semiconductor device assemblies may be packaged into stacked semiconductor devices.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a logic die;
a first plurality of stacked memory dies electrically coupled with the logic die at a first lateral location;
a second plurality of stacked memory dies electrically coupled with the logic die at a second lateral location different from the first lateral location;
a first dielectric material disposed at the logic die between the first plurality of stacked memory dies and the second plurality of stacked memory dies;
a third plurality of stacked memory dies mounted on and electrically coupled with the first plurality of stacked memory dies;
a fourth plurality of stacked memory dies mounted on and electrically coupled with the second plurality of stacked memory dies;
a second dielectric material disposed at the first dielectric material between the third plurality of stacked memory dies and the fourth plurality of stacked memory dies; and
a third dielectric material disposed over the first plurality of stacked memory dies, the second plurality of stacked memory dies, and the first dielectric layer, the third dielectric material coupling the third plurality of stacked memory dies, the fourth plurality of stacked memory dies, and the second dielectric material couple with the first plurality of stacked memory dies, the second plurality of stacked memory dies, and the first dielectric layer, respectively.

2. The semiconductor device assembly of claim 1, wherein a first thickness of the third dielectric material between the first dielectric material and the second dielectric material is greater than a second thickness of the third dielectric material between the third plurality of stacked memory dies and the first plurality of stacked memory dies.

3. The semiconductor device assembly of claim 1, wherein the first plurality of stacked memory dies includes respective first interconnects coupling a respective first memory die and a respective second memory die of the first plurality of stacked memory dies, the respective first interconnects electrically coupled between respective first contact pads at the respective first memory die and respective second contact pads at the respective second memory die.

4. The semiconductor device assembly of claim 3, wherein:
the first plurality of stacked memory dies includes a top memory die having third contact pads;
the third plurality of stacked memory dies includes a bottom memory die having fourth contact pads;
the semiconductor device assembly includes second interconnects electrically coupling the third contact pads and the fourth contact pads; and
the third contact pads and the fourth contact pads have a greater misalignment than the respective first contact pads and the respective second contact pads.

5. The semiconductor device assembly of claim 1, further comprising:
a fifth plurality of stacked memory dies mounted on and electrically coupled with the third plurality of stacked memory dies;
a sixth plurality of stacked memory dies mounted on and electrically coupled with the fourth plurality of stacked memory dies; and
a fourth dielectric material disposed at the second dielectric material between the fifth plurality of stacked memory dies and the sixth plurality of stacked memory dies.

6. The semiconductor device assembly of claim 1, wherein the first plurality of memory dies includes four memory dies.

7. A method for fabricating a semiconductor device assembly, comprising:
providing a wafer of logic dies;
providing a first plurality of stacked semiconductor dies;
providing a second plurality of stacked semiconductor dies;
coupling the first plurality of stacked semiconductor dies to the wafer of logic dies at a first lateral location;
coupling the second plurality of stacked semiconductor dies to the wafer of logic dies at a second lateral location different from the first lateral location;
disposing a first dielectric material at the wafer of logic dies between the first plurality of stacked semiconductor dies and the second plurality of stacked semiconductor dies;
providing a third plurality of stacked semiconductor dies;
providing a fourth plurality of stacked semiconductor dies;
mounting the third plurality of stacked semiconductor dies to the first plurality of stacked semiconductor dies to electrically couple the third plurality of stacked semiconductor dies and the first plurality of stacked semiconductor dies;
mounting the fourth plurality of stacked semiconductor dies to the first plurality of stacked semiconductor dies to electrically couple the fourth plurality of stacked semiconductor dies and the second plurality of stacked semiconductor dies; and
disposing a second dielectric material at the first dielectric material between the third plurality of stacked semiconductor dies and the fourth plurality of stacked semiconductor dies.

8. The method of claim 7, further comprising disposing a third dielectric material between the third plurality of stacked memory dies, the fourth plurality of stacked memory dies, and the second dielectric material and the first plurality of stacked memory dies, the second plurality of stacked memory dies, and the first dielectric layer, respectively.

9. The method of claim 7, wherein providing the third plurality of semiconductor dies includes:
providing a plurality of semiconductor wafers each including a respective plurality of semiconductor dies;
electrically coupling the plurality of semiconductor wafers to form a stack of semiconductor wafers; and
dicing the stack of semiconductor wafers to create the third plurality of stacked semiconductor dies.

10. The method of claim 9, further comprising:
dicing the stack of semiconductor wafers to create multiple pluralities of stacked semiconductor dies;
probing the multiple pluralities of stacked semiconductor dies to determine a quality of the multiple pluralities of stacked semiconductor dies; and
selecting the third plurality of stacked semiconductor dies from the multiple pluralities of stacked semiconductor dies based on the quality.

11. The method of claim 7, wherein the first plurality of stacked semiconductor dies includes a first top memory die having first through-silicon vias (TSVs) and the second plurality of stacked semiconductor dies includes a second top memory die having second TSVs, the method further comprising:
disposing the first dielectric material at the first top memory die and the second top memory die such that an upper surface of the first dielectric material extends from the first top memory die and the second top memory die; and
thinning the first dielectric material, the first top memory die, and the second top memory die to expose the first TSVs and the second TSVs.

12. The method of claim 11, further comprising:
forming first contact pads at the first TSVs;
forming second contact pads at the second TSVs;
coupling the third plurality of stacked semiconductor dies to the first contact pads; and
coupling the fourth plurality of stacked semiconductor dies to the second contact pads.

13. The method of claim 7, further comprising:
dicing the wafer of logic dies, the first dielectric material, and the second dielectric material effective to create a first stacked semiconductor device assembly and a second stacked semiconductor device assembly,
wherein the first stacked semiconductor device assembly includes a first logic die from the wafer of logic dies, the first plurality of stacked semiconductor dies, and the third plurality of stacked semiconductor dies, and
wherein the second stacked semiconductor device assembly includes a second logic die from the wafer of logic dies, the second plurality of stacked semiconductor dies, and a fourth plurality of stacked semiconductor dies.

14. A semiconductor device assembly, comprising:
a logic die;
a first plurality of stacked memory dies electrically coupled with the logic die;
a first dielectric material disposed around the first plurality of stacked memory dies;
a second plurality of stacked memory dies mounted on and electrically coupled with the first plurality of stacked memory dies; and
a second dielectric material disposed at the first dielectric material and surrounding the second plurality of stacked memory dies,
wherein the second plurality of stacked memory dies and the second dielectric material couple with the first plurality of stacked memory dies and the first dielectric layer, respectively, through a third dielectric material.

15. The semiconductor device assembly of claim 14, wherein a first thickness of the third dielectric material between the first dielectric material and the second dielectric material is greater than a second thickness of the third dielectric material between the second plurality of stacked memory dies and the first plurality of stacked memory dies.

16. The semiconductor device assembly of claim 14, wherein the first plurality of stacked memory dies includes respective first interconnects coupling a respective first memory die and a respective second memory die of the first plurality of stacked memory dies, the respective first interconnects electrically coupled between respective first contact pads at the respective first memory die and respective second contact pads at the respective second memory die.

17. The semiconductor device assembly of claim 16, wherein:
the first plurality of stacked memory dies includes a top memory die having third contact pads;
the second plurality of stacked memory dies includes a bottom memory die having fourth contact pads;
the semiconductor device assembly includes second interconnects electrically coupling the third contact pads and the fourth contact pads; and
the third contact pads and the fourth contact pads have a greater misalignment than the respective first contact pads and the respective second contact pads.

18. The semiconductor device assembly of claim 16, wherein the respective first interconnects have a vertical height less than 500 nanometers.

19. The semiconductor device assembly of claim 14, wherein the first dielectric material or the second dielectric material includes an oxide.

20. The semiconductor device assembly of claim 14, wherein the third dielectric material is different from the first dielectric material and the second dielectric material.
